(19) United States
(12) Patent Application Publication
(10) Pub. No.: US 2025/0295013 A1
(43) Pub. Date: Sep. 18, 2025

(54) DISPLAY APPARATUS AND METHOD FOR MANUFACTURING SAME

(71) Applicant: CANON KABUSHIKI KAISHA, Tokyo (JP)

(72) Inventors: MASAO ISHIOKA, Tokyo (JP); AKINORI MAKAINO, Kanagawa (JP)

(21) Appl. No.: 19/064,540

(22) Filed: Feb. 26, 2025

(30) Foreign Application Priority Data
Mar. 13, 2024 (JP) 2024-038938

(51) Int. Cl. H10K 59/80; H10K 59/12

(52) U.S. Cl. CPC H10K 59/878; H10K 59/1201; H10K 59/8791

(57) ABSTRACT

An apparatus that has an interference structure and reduces a variation in light emission characteristics between pixels of respective colors. In the apparatus in which a thickness of a first insulating layer arranged between a reflection layer and a first electrode is different between the pixels of different light emission colors, an area gradation mask is used to form a photoresist having a gradient in film thickness, and an insulating film is etched to form the first insulating layer, so that a difference in angle A between the pixels of the respective colors falls within ±10%, where the angle A is formed by a slanted surface of the first insulating layer on an end portion of the reflection layer with respect to a first surface of a substrate.

### BACKGROUND OF THE INVENTION

### Technical Field

The aspect of the embodiments relates to a display apparatus and a method for manufacturing the same.

### Description of the Related Art

Contemporary display apparatuses using an organic electroluminescence element (EL element) employ an interference structure using a transparent electrode to enhance performance. The transparent electrode transmits the light emitted from the organic EL element, and a resonance structure is formed by reflection and interference of the light which has been transmitted through the transparent electrode, so that light emission efficiency is enhanced. Japanese Patent Application Laid-Open No. 2021-72282 (hereinafter PTL 1) discusses a light emitting element with interference of light using a transparent electrode. In PTL 1, a reflection layer, an insulating layer, a lower-portion electrode, an organic layer, and a transparent electrode are formed, and a film thickness of the insulating layer is optimized for each color pixel to enhance an interference effect.

In the interference structure discussed in PTL 1, an insulating film surface in a region between pixels has a step, and the insulating film surface has a slanted surface having an angle with respect to a substrate surface in the vicinity of an end portion of a light emitting region. Herein, a film thickness of the insulating layer inside a pixel of each color differs, whereas a film thickness in the region between pixels of respective colors remains constant. Thus, a step thereof has a different value for each pixel. In PTL 1, formation of the insulating layer and etching are repeated for each pixel to form such a structure. However, since an amount of the insulating film in the etching process differs for each pixel, an angle of the slanted surface in each of the pixels after the formation of the structure can have a different value. For example, in a case where an interference film thickness for each color is designed to λ/4 with respect to a wavelength λ, a blue pixel, a green pixel, and a red pixel have a relation of the blue pixel<the green pixel<the red pixel in terms of a film thickness of a first insulating layer on a reflection layer. However, an angle of the step portion in the blue pixel can be steepest. Here, a lower portion electrode, an organic layer, and a transparent electrode to be formed on a slanted surface of an insulating film surface can be relatively thinner as an angle of the slanted surface is steeper. Consequently, a variation in light emission characteristics tends to occur.

### SUMMARY OF THE INVENTION

According to an aspect of the embodiments, an apparatus includes a first pixel and a second pixel arranged on a first surface of a substrate, the first pixel and the second pixel each including a reflection layer, a first insulating layer, a first electrode, a second insulating layer configured to cover an end portion of the first electrode, a compound layer configured to cover the first electrode and the second insulating layer, and a second electrode configured to cover the compound layer, that are arranged in this order, wherein the first pixel and the second pixel differ from each other in a distance between the reflection layer and the first electrode, and wherein the first pixel and the second pixel differ in an angel A formed by a slanted surface of the first insulating layer on an end portion of the reflection layer with respect to the first surface, and a difference of the angle A falls within ±10%.

According to another aspect of the embodiments, a method for manufacturing an apparatus including a first pixel and a second pixel on a first surface of a substrate includes forming a reflection layer for each of the plurality of pixels on the first surface of the substrate, forming a first insulating layer on the reflection layer such that the first pixel and the second pixel differ in thickness of the first insulating layer, the first pixel and the second pixel differ in an angle A formed between a slanted surface formed on an end portion of the reflection layer and the first surface of the substrate and a difference in the angle A falls within ±10%, forming a first electrode on the first insulating layer for each pixel, forming a second insulating layer configured to cover an end portion of the first electrode, forming a compound layer configured to cover the first electrode and the second insulating layer, and forming a second electrode configured to cover the compound layer.

Further features of the disclosure will become apparent from the following description of exemplary embodiments with reference to the attached drawings.

### BRIEF DESCRIPTION OF THE DRAWINGS

FIG. 1 is a schematic sectional view in a thickness direction of a display apparatus according to one exemplary embodiment of the disclosure.

FIGS. 2A through 2C are process charts for manufacturing the display apparatus illustrated in FIG. 1.

FIGS. 3A through 3C are process charts for manufacturing the display apparatus illustrated in FIG. 1.

FIGS. 4A through 4C are diagrams each illustrating an angle formed by a slanted surface of a first insulating layer and a first surface of a substrate in the display apparatus.

FIGS. 5A through 5C are diagrams of an etching process using an area gradation mask.

FIGS. 6A through 6C are process charts for manufacturing a display apparatus by using a related-art technique.

FIGS. 7A through 7C are process charts for manufacturing a display apparatus by using a related-art technique.

FIGS. 8A and 8B are schematic sectional views of a configuration of a first insulating layer in the display apparatus manufactured by using the related art technique.

### DESCRIPTION OF THE EMBODIMENTS

Hereinafter, an exemplary embodiment of the disclosure is described in detail. However, the disclosure is not limited to the following exemplary embodiment. Although a plurality of aspects is described in the exemplary embodiment, not all of the aspects are necessarily required for the disclosure, and the plurality of aspects can be optionally combined. In the drawings, similar or the same configurations are given the same reference numerals, and redundant descriptions thereof are omitted.

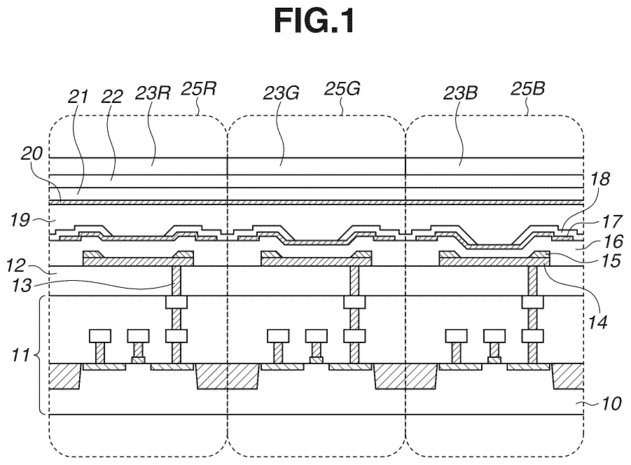

FIG. 1 is a sectional view of a display apparatus including an organic electroluminescence (EL) element according to one exemplary embodiment of the disclosure. In the present exemplary embodiment, a drive circuit layer 11 is arranged on a substrate 10, and an interlayer film 12 having an insulation property is arranged on the drive circuit layer 11. A surface of the interlayer film 12 is flattened. The organic EL element is arranged above the interlayer film 12, and the drive circuit layer 11 and a reflection layer 14 are connected via a conductive plug 13. For example, the conductive plug 13 can be a W plug having barrier metal such as titanium (Ti) or titanium nitride (TiN). An antireflection layer 15 is arranged on the reflection layer 14. Since the antireflection layer 15 increases a reflectance, an area of a center portion of the reflection layer 14 is removed by, for example, a photolithography method and a dry etching method.

On the antireflection layer 15, a first insulating layer 16, a first electrode 17 functioning as an anode, a second insulating layer 18, an organic compound layer 19, a second electrode 20 functioning as a cathode, a moisture-proof layer 21, a planarization layer 22, and a color filter 23 are laminated in this order. In one embodiment, the first electrode 17 is a transparent material to cause light emitted from the organic compound layer 19 toward the substrate 10 to passes through. For example, the first electrode 17 is formed of indium tin oxide (ITO) or indium zinc oxide (IZO). The thinner the transparent material, the greater the reduction in absorption of light. Thus, the thinner transparent material has the advantage in electrical power consumption. The first electrode 17 and the drive circuit layer 11 are electrically connected via a connecting portion (not illustrated). This connecting portion may include the reflection layer 14 or the antireflection layer 15.

The display apparatus according to the present exemplary embodiment includes a first pixel 25R, a second pixel 25G, a third pixel 25B each having the aforementioned structure, and the first, second, and third pixels 25R, 25G, and 25B respectively include a first color filter 23R, a second color filter 23G, and a third color filter 23B of different colors. The first, second, and third pixels 25R, 25G, and 25B are differ from each other in color of light to be emitted to the outside from the organic EL display apparatus. For example, the first pixel 25R emits red (R) light, the second pixel 25G emits green (G) light, and the third pixel 25B emits blue (B) light. The organic EL display apparatus according to the present exemplary embodiment can include a plurality of first pixels 25R, a plurality of second pixels 25G, and a plurality of third pixels 25B. The present exemplary embodiment is described using an example in which three different colors of light are generated. However, the present exemplary embodiment is not limited thereto.

In the display apparatus according to the present exemplary embodiment, an electric signal is transmitted from the drive circuit layer 11 formed on the substrate 10 to the first electrode 17, and light is generated by the organic compound layer 19. The light emitted from the organic compound layer 19 toward the substrate 10 is reflected by the reflection layer 14. In each of the first pixel 25R, the second pixel 25G, and the third pixel 25B, the light emitted from the organic compound layer 19 toward the second electrode 20 and the light reflected by the reflection layer 14 resonate and are amplified in an area in which the antireflection layer 15 is not present directly underneath the first insulating layer 16. Such amplified light is emitted via each of the color filters 23R, 23G, and 23B.

When light is emitted from the organic compound layer 19 toward the substrate 10, a wavelength of the light emitted by each of the pixels differs. In other words, a wavelength for resonance and amplification differs for each pixel.

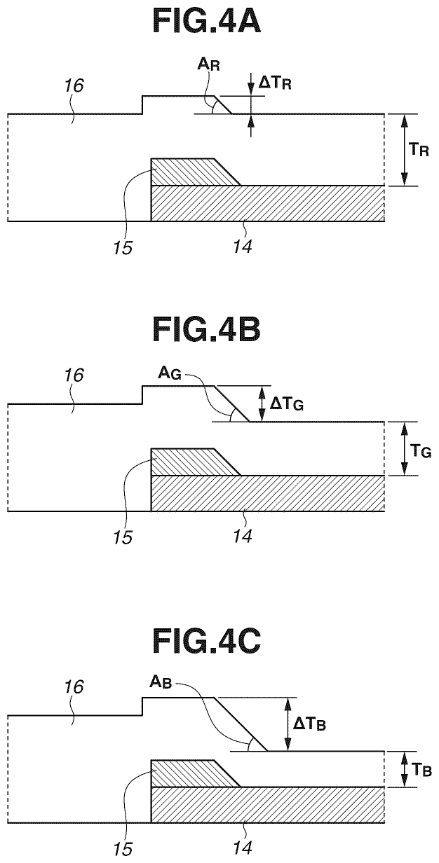

The first pixel 25R, the second pixel 25G, and the third pixel 25B each have a center portion including an area in which the antireflection layer 15 is not arranged. If film thicknesses of the first insulating layers 16 of the first, second, and third pixels 25R, 25G, and 25B in such areas are represented by T_{R}, T_{G}, and T_{B}, these film thicknesses T_{R}, T_{G}, and T_{B} have mutually different values. Similarly, if steps provided between the aforementioned center portions of the pixels 25R, 25G, and 25B and respective pixel peripheries are represented by ΔT_{R}, ΔT_{G}, and ΔT_{B}, these steps ΔT_{R}, ΔT_{G}, and ΔT_{B} also have mutually different values. The first insulating layer 16 has a surface that is slanted from an area near an end of the center portion of the pixel toward the pixel periphery. Angles Δ_{R}, Δ_{G}, and Δ_{B} formed by the slanted surfaces of the first insulating layers 16 with respect to a first surface of the substrate 10 are controlled such that the angles Δ_{R}, Δ_{G}, and Δ_{B} are roughly constant regardless of values of the film thicknesses T_{R}, T_{G}, and T_{B}. In one embodiment, the angles Δ_{R}, Δ_{G}, and Δ_{B} have values with a difference that falls within a range of −10% to 10% in terms of relative ratio. Accordingly, a film thickness of the first electrode 17 to be laminated on the surface of the first insulating layer 16 can be controlled to fall within a certain range. Each of FIGS. 4A through 4C illustrates a film thickness of the first insulating layer 16 and an angle of the slanted surface. FIGS. 4A, 4B, and 4C respectively illustrate the first pixel 25R, the second pixel 25G, and the third pixel 25B.

In an uppermost portion and a lowermost portion of the slanted surface of the first insulating layer 16, the angle A continuously changes.

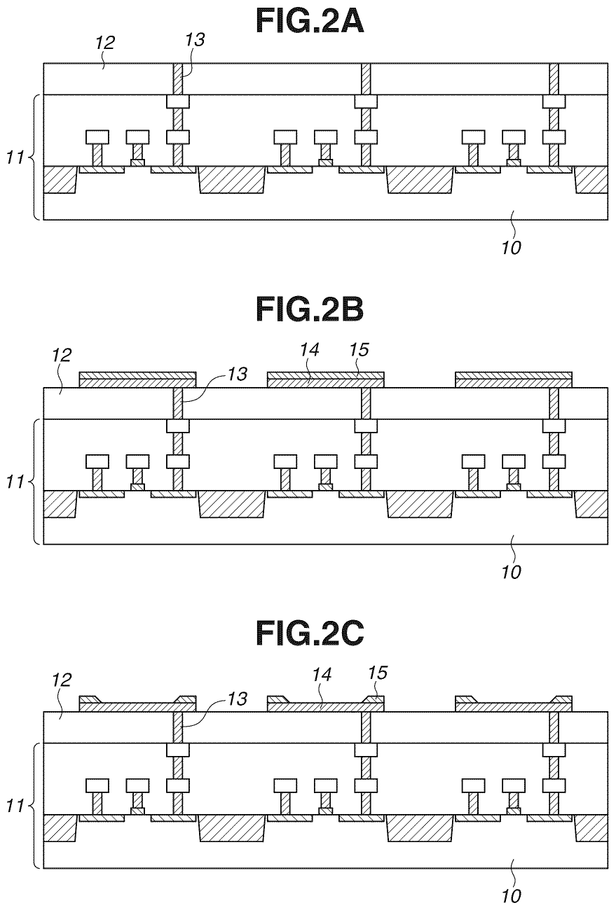

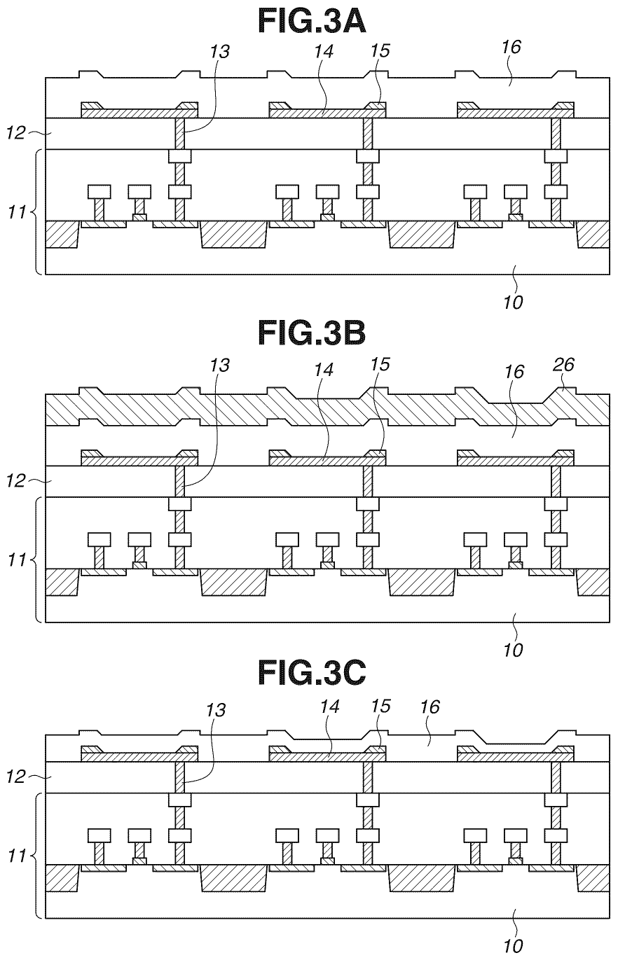

Next, a manufacturing method for the display apparatus according to the present exemplary embodiment is described with reference to FIGS. 2A through 2C and FIGS. 3A through 3C.

Each of FIGS. 2A through 2C and FIGS. 3A through 3C is a schematic sectional view in a thickness direction and illustrates a process of the manufacturing method.

First, as illustrated in FIG. 2A, the drive circuit layer 11 including a capacitor and a transistor of a drive circuit is formed on the substrate 10 by a known complementary metal-oxide-semiconductor (CMOS) process. Next, the interlayer film 12 is formed by formation of an insulating film such as an oxide film (e.g., a silicone oxide (SiOx) film) and an oxynitride film (e.g., a silicon oxynitride (SiON) film) by a plasma chemical vapor deposition (CVD) method, a high-density plasma method, or a combination of the plasma CVD method and the high-density plasma method. After the interlayer film 12 is formed, a surface including a pixel region of the interlayer film 12 can be flattened by, for example, a chemical mechanical polishing (CMP) method. Then, in the interlayer film 12, a plurality of openings is formed in predetermined positions by a photolithography method and a dry etching method. In each of the openings, for example, tungsten (W) is arranged, and an excess portion is removed by a CMP method or an etch back method. Thus, the conductive plug 13 including a conductive material (tungsten) is formed.

Next, as illustrated in FIG. 2B, a laminated metal film including titanium (Ti), titanium nitride (TiN), and aluminum alloy is formed on the interlayer film 12 by, for example, a sputtering method, and the resultant laminated metal film is patterned to be in a predetermined shape by a photolithography method and a dry etching method or a wet etching process. Accordingly, a plurality of the antireflection layers 15 and the reflection layers 14 connected to the aforementioned conductive plugs 13 are formed in a display region.

Subsequently, as illustrated in FIG. 2C, a plurality of openings is formed in predetermined positions of the antireflection layers 15 by a photolithography method and a dry etching method such that the reflection layers 14 become uppermost surfaces. The presence of the antireflection layer 15 enhances the accuracy of photolithography, so that shaping can be performed in a finer manner. In one embodiment, the opening has an end that is formed in a tapered shape having an angle between approximately 50 degrees and 70 degrees, but is not limited thereto.

Next, as illustrated in FIG. 3A, the first insulating layer 16 is formed on the reflection layer 14 by formation of an insulating layer, for example, an oxide film (e.g., a SiOx film), an oxynitride film (e.g., a SiON film), and a silicon nitride (SiNx) film by a plasma CVD method.

Subsequently, as illustrated in FIG. 3B, a pattern of a photoresist 26 is formed by a photolithography method. Then, as illustrated in FIG. 3C, an opening is formed in one portion of the first insulating layer 16 in an area to be a pixel. The opening is formed by a dry etching method or a wet etching method. Herein, an area gradation mask or a halftone mask is used in the photolithography to control a film thickness of the first insulating layer 16 after the etching, and a shape of the photoresist 26 is controlled by patterning the photoresist 26 such that not only a film thickness of a pixel center portion in which the antireflection layer 15 is not formed is made small, but also the angle of inclination between the area near the end of the pixel center portion and the pixel periphery above the reflection layer 14 is roughly constant. In FIG. 3B, a shape of the reflection layer 14 is transferred, so that the photoresist 26 also has a protrusion in the pixel periphery. However, the present exemplary embodiment is not limited thereto. A pixel periphery can be formed to have a thickness that is substantially equal to a thickness of a region between pixels.

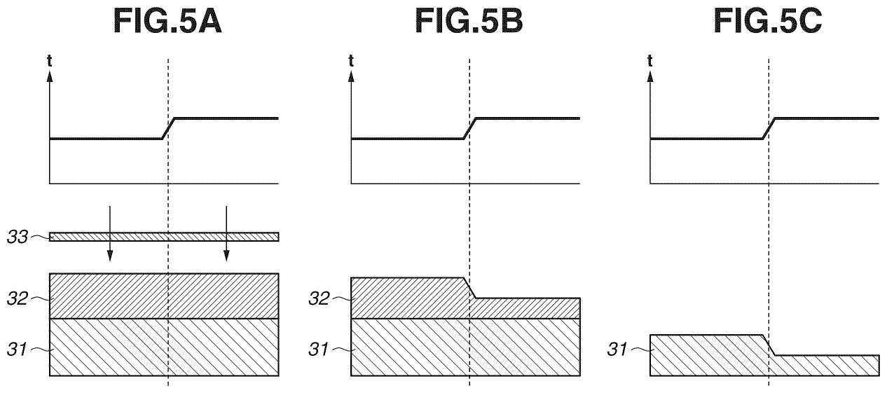

FIGS. 5A through 5C illustrate the principle of film thickness adjustment using an area gradation mask. The area gradation mask has characteristics in which a tiny opening pattern having a size of an exposure wavelength or less is arranged in a dotted manner, and an opening ratio t thereof has optional distribution inside the mask. For example, as illustrated in FIG. 5A, an area gradation mask 33 having distribution with a low opening ratio t in the left portion of FIG. 5A and a high opening ratio t in the right portion may be used, and a positive-type photoresist 32 applied on an etching material 31 may be exposed to perform photolithography. In such case, in a portion having a low opening ratio t as illustrated in FIG. 5B, since a melting amount of the photoresist 32 is smaller, a residual film amount is larger. On the other hand, a residual film amount is smaller in a portion having a high opening ratio t. In a case where etching is performed in a state in which a film thickness of the photoresist 32 has such distribution, a shape of the photoresist 32 is transferred to the etching material 31 as illustrated in FIG. 5C, and a film thickness of the etching material 31 after the etching can have distribution.

Accordingly, a shape of the photoresist is controlled and patterned as illustrated in FIG. 3B by using the area gradation mask, and etching is further performed, thereby enabling film thicknesses T_{R}, T_{G}, and T_{B} of the respective first insulating layers 16 after the etching to differ as illustrated in FIGS. 3F and 4A through 4C. Moreover, since a transmission rate of the area gradation mask is continuously changed, an inclination angle can also be optionally controlled, and a desired shape in which the angles Δ_{R}, Δ_{G}, and Δ_{B} are kept almost constant can be obtained. After such processes, components from the organic compound layer 19 to the color filter 23 are formed by a known method, so that a desired organic EL display apparatus can be manufactured.

The exemplary embodiment has been described using an example in which film thicknesses corresponding to wavelengths of light of three different colors are formed by insulating film formation, photolithography, and etching each of which is performed one time. However, the present exemplary embodiment is not limited thereto. Each of such processes can be performed multiple times. For example, for three types of pixels, insulating film formation, photolithography, and etching may be performed in each case, or insulating film formation may be collectively performed, and then photolithography and etching may be performed multiple times.

In a case where photolithography and etching are performed multiple times to form the aforementioned film thickness, an area gradation mask may be used in only a part of the processes.

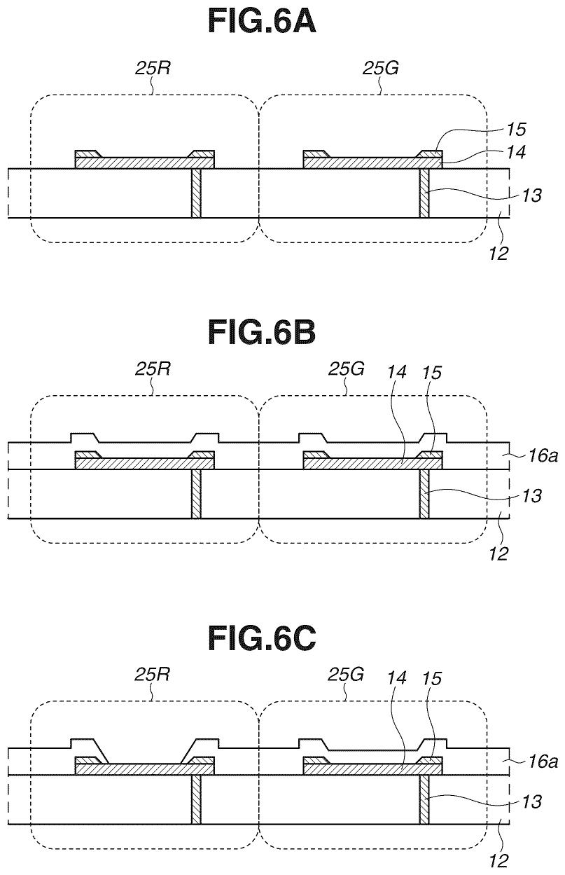

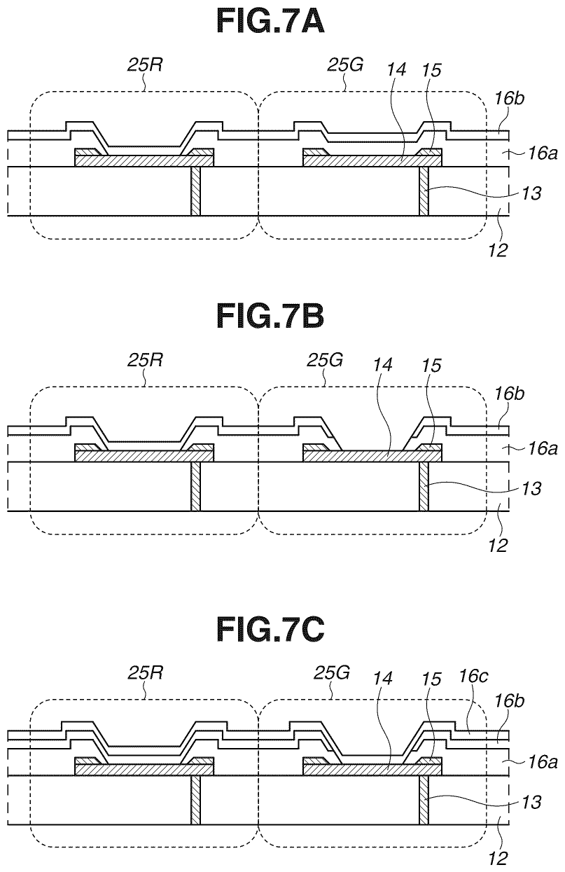

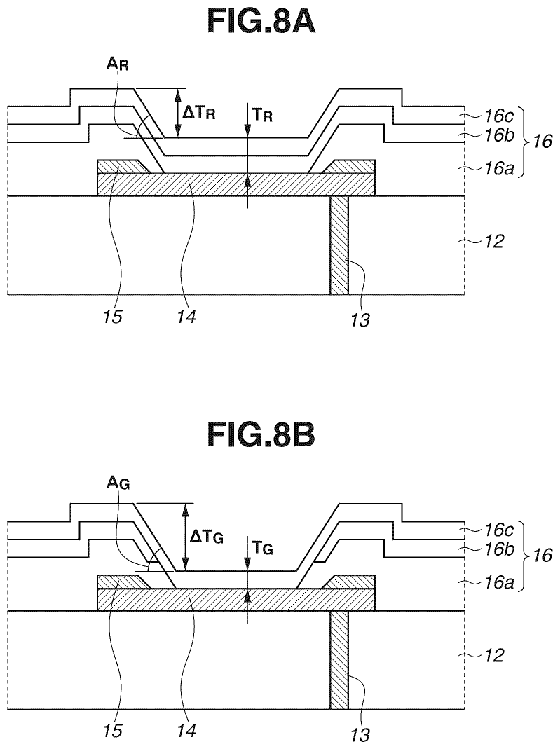

FIGS. 6A through 6C and FIGS. 7A through 7C illustrate processes by which a first insulating layer 16 of the display apparatus illustrated in FIG. 1 is formed by the manufacturing method discussed in PTL 1 to compare the manufacturing method according to the present exemplary embodiment with the manufacturing method discussed in PTL 1. In each of FIGS. 6A through 6C and FIGS. 7A through 7C, only a first pixel 25R and a second pixel 25G are illustrated for the sake of simplicity. Moreover, FIGS. 8A and 8B are enlarged views of the first pixel 25R and the second pixel 25G formed by the processes illustrated in FIGS. 6A through 6C and FIGS. 7A through 7C. Any of FIGS. 6A through 6C, FIGS. 7A through 7C, and FIGS. 8A and 8B is a schematic sectional view in a thickness direction.

As illustrated in FIG. 6A, a reflection layer 14 and an antireflection layer 15 are formed. Next, as illustrated in FIG. 6B, a first insulating layer 16a is formed. Then, as illustrated in FIG. 6C, the first insulating layer 16a on the reflection layer 14 of only the first pixel 25R is removed by a known dry-etching method. Subsequently, after a second insulating layer 16b is formed as illustrated in FIG. 7A, the first insulating layer 16a and the second insulating layer 16b on the reflection layer 14 of the second pixel 25G are removed, as illustrated in FIG. 7B, by the dry-etching method again. Then, as illustrated in FIG. 7C, a third insulating film 16c is formed. Accordingly, film formation and etching are repeated on a pixel basis, so that each of film thicknesses T_{R} and T_{G} of the first insulating layers 16 forming a part of an optical resonance layer can be adjusted as illustrated in FIGS. 8A and 8B. FIG. 8A is an enlarged view of the first pixel 25R illustrated in FIG. 7C, and FIG. 8B is an enlarged view of the second pixel 25G illustrated in FIG. 7C.

According to such a manufacturing method, a film thickness of an etching film when an insulating film is dry-etched differs for each pixel. When the first insulating layer 16a or the second insulating layer 16b is dry-etched, etching can also proceed in a direction parallel to a substrate. Consequently, a change in the film thickness of the etching film can cause an angle A (angles Δ_{R} and Δ_{G} in the respective FIGS. 8A and 8B) formed between a slanted surface of the dry-etched first insulating layer 16 and a first surface of the substrate to have a different value for each pixel. A film thickness of a first electrode 17 or an organic compound layer 19 to be formed on the slanted surface of the first insulating layer 16 can differ depending on the angle A. Thus, in such a configuration, a variation in leakage current between pixels or a variation in driving current for each pixel can cause a variation in light emission characteristics. According to the present exemplary embodiment, on the other hand, an angle A is substantially the same for each pixel, so that a good display apparatus having a smaller variation in light emission characteristics can be obtained.

In the present exemplary embodiment, an angle of a slanted surface of an insulating layer on a reflection layer of each of pixels is formed substantially equal, and thus a display apparatus in which a variation in light emission characteristics is reduced can be provided.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-038938, filed Mar. 13, 2024, which is hereby incorporated by reference herein in its entirety.

What is claimed is:

1. An apparatus comprising:
a first pixel and a second pixel arranged on a first surface of a substrate, the first pixel and the second pixel each including a reflection layer, a first insulating layer, a first electrode, a second insulating layer configured to cover an end portion of the first electrode, a compound layer configured to cover the first electrode and the second insulating layer, and a second electrode configured to cover the compound layer, that are arranged in this order,
wherein the first pixel and the second pixel differ from each other in a distance between the reflection layer and the first electrode, and
wherein the first pixel and the second pixel differ in an angel A formed by a slanted surface of the first insulating layer on an end portion of the reflection layer with respect to the first surface, and a difference of the angle A falls within ±10%.

2. The apparatus according to claim 1, further comprising an antireflection film on the end portion of the reflection layer,
wherein the slanted surface of the first insulating layer is formed by the antireflection layer and the reflection layer.

3. The apparatus according to claim 1, wherein the first pixel and the second pixel are substantially equal in the angle A.

4. The apparatus according to claim 1, wherein, the angle A is between 50 degrees and 70 degrees in any of the first pixel and the second pixel.

5. The apparatus according to claim 1, wherein the angle A in an uppermost portion and a lowermost portion of the slanted surface of the first insulating layer continuously changes.

6. The apparatus according to claim 1, further comprising a third pixel,
wherein the third pixel differs from the first pixel and the second pixel in a distance between the reflection layer and the first electrode, and a difference in the angle A among the first through third pixels falls within ±10%.

7. The apparatus according to claim 6, wherein the first pixel, the second pixel, and the third pixel have a relation of the first pixel<the second pixel<the third pixel in terms of a distance between the reflection layer and the first insulating layer.

8. The apparatus according to claim 7, comprising a color filter above the second electrode of each of the first through third pixels,
wherein the first pixel, the second pixel, and the third pixel have a relation of the first pixel<the second pixel<the third pixel in terms of a wavelength of transmission light of the color filter on each of the pixels.

9. The apparatus according to claim 1, wherein each of the first pixel and the second pixel includes a transistor.

10. A method for manufacturing an apparatus including a first pixel and a second pixel on a first surface of a substrate, the method comprising:
forming a reflection layer for each of the plurality of pixels on the first surface of the substrate;
forming a first insulating layer on the reflection layer such that the first pixel and the second pixel differ in thickness of the first insulating layer, the first pixel and the second pixel differ in an angle A formed between a slanted surface formed on an end portion of the reflection layer and the first surface of the substrate and a difference in the angle A falls within ±10%;
forming a first electrode on the first insulating layer for each pixel;
forming a second insulating layer configured to cover an end portion of the first electrode;
forming a compound layer configured to cover the first electrode and the second insulating layer; and
forming a second electrode configured to cover the compound layer.

11. The method according to claim 10,
wherein the formation of the first insulating layer includes:
forming an insulating film across an entire surface of the substrate;
forming a photoresist on the insulating film; and
performing etching, and
wherein, above the reflection layer, the photoresist has a gradient in film thickness and the gradient is substantially constant in the first pixel and the second pixel.

12. The method according to claim 11,
wherein, in the formation of the photoresist, an area gradation mask or a halftone mask is used to form the gradient in the film thickness of the photoresist.

13. The method according to claim 10, wherein the first insulating layer in the first pixel and the first insulating layer in the second pixel are formed at same time.

14. The method according to claim 10, further comprising forming an antireflection film on the end portion of the reflection layer,
wherein the slanted surface of the first insulating layer is formed by the antireflection layer and the reflection layer.

15. The method according to claim 10, wherein the first pixel and the second pixel are substantially equal in the angle A.

16. The method according to claim 10, wherein, the angle A is between 50 degrees and 70 degrees in any of the first pixel and the second pixel.

17. The method according to claim 10, wherein the angle A in an uppermost portion and a lowermost portion of the slanted surface of the first insulating layer continuously changes.

18. The method according to claim 10, the apparatus further includes a third pixel,
wherein the third pixel differs from the first pixel and the second pixel in a distance between the reflection layer and the first electrode, and a difference in the angle A among the first through third pixels falls within ±10%.

19. The method according to claim 18, wherein the first pixel, the second pixel, and the third pixel have a relation of the first pixel<the second pixel<the third pixel in terms of a distance between the reflection layer and the first insulating layer.

20. The method according to claim 10, wherein each of the first pixel and the second pixel includes a transistor.
